(19) United States
(12) Patent Application Publication
(10) Pub. No.: US 2026/0075979 A1
(43) Pub. Date: Mar. 12, 2026

(54) I-III-VI BASED QUANTUM DOTS AND FABRICATION METHOD THEREOF

(71) Applicant: Hongik University Industry-Academia Cooperation Foundation, Seoul (KR)

(72) Inventors: Hee-Sun YANG, Seoul (KR); Yuri KIM, Gimpo-si (KR)

(21) Appl. No.: 18/897,842

(22) Filed: Sep. 26, 2024

(30) Foreign Application Priority Data
Sep. 11, 2024 (KR) 10-2024-0124246

(51) Int. Cl. H01L 31/0352; H01L 31/032; H01L 31/18

(52) U.S. Cl. CPC H10F 77/1433; H10F 71/00; H10F 77/126

(57) ABSTRACT

There are provided I-III-VI based quantum dots added with Cu with narrow full width at half maximum for use as display materials and a method for fabricating the same. The quantum dots according to the present disclosure include a core including Cu, Group 13 element and Group 16 element; and a shell on the core, wherein the core optionally further includes Group 11 element other than the Cu, and wherein the quantum dots exhibit band-edge emission in a visible light region and an infrared region.

### CROSS-REFERENCE TO RELATED APPLICATIONS

This application is based on and claims priority from Korean Patent Application No. 10-2024-0124246, filed on Sep. 11, 2024, with the Korean Intellectual Property Office, the disclosure of which is incorporated herein in their entireties by reference.

### TECHNICAL FIELD

The present disclosure relates to quantum dots of non Cd composition and a method for fabricating the same, and more particularly, to I-III-VI based quantum dots and a method for fabricating the same. More particularly, the present disclosure relates to I-III-VI based quantum dots with narrow full width at half maximum and a method for fabricating the same.

### BACKGROUND

Quantum dots are semiconductor particles a few tens of nm or less in size, and as opposed to bulk materials, they exhibit various characteristics depending on the size and composition of the particles and have optical and electrical properties that the commonly used semiconducting materials do not have. The quantum dots have better optical properties such as narrower full width at half maximum and higher emission intensity than organic material based fluorescent dyes, and since they are made of inorganic materials, they have a stability advantage. Due to these features, quantum dots are attracting significant attention as materials of color filters for displays, light emitting diodes (LEDs), biosensors, lasers and solar cells.

Typically, compound semiconductor compositions made up of Group II-VI elements on the periodic table have been studied, but high efficiency quantum dots include hazardous materials to humans such as Cd or Pb, which makes it difficult to use in industrial applications. Compound semiconductors made up of Group III-V elements typically include InP quantum dots, and InP quantum dots have quantum efficiency of 95% or more and narrow full width at half maximum of 40 nm or less, and thus are used in a wide range of industrial applications. In display applications, InP quantum dots are used for a photoconversion layer (a color filter for display) on a blue LED. They are excited by blue light to re-emit red and green light, producing color, and when quantum dots are small in size, they have difficulty in sufficient light absorption. The core diameter of green InP quantum dots is about 2 nm to 2.5 nm, and the core diameter of red InP quantum dots is 3 nm to 3.5 nm. The red InP quantum dots having larger particle size exhibit higher absorbance than green InP quantum dots, but compared to Cd based quantum dots, red InP quantum dots have high absorbance due to low blue light conversion efficiency, so research of eco-friendly alternative materials is needed.

I-III-VI based quantum dots typically include Cu—In—S and Ag—In—S, and the composition typically includes Group III elements and further includes Ga. Usually, I-III-VI based quantum dots exhibit defect state emission, not band-edge emission, and broad full width at half maximum of 100 nm or more, which makes the use as display materials difficult, and they are used in solar cell or infrared device applications. To use I-III-VI based quantum dots as display materials, it requires narrow full width at half maximum of 60 nm or less, dominant band-edge emission and high quantum efficiency.

### DISCLOSURE

### Technical Problem

The present disclosure is directed to providing I-III-VI based quantum dots added with Cu with narrow full width at half maximum and larger particle size than red InP quantum dots for use as display materials and a method for fabricating the same.

### Technical Solution

To solve the above-described problem, a quantum dot according to the present disclosure includes a core including Cu, Group 13 element and Group 16 element; and a shell on the core, wherein the core optionally further includes Group 11 element other than the Cu, and wherein the quantum dot exhibits band-edge emission in a visible light region and an infrared region.

The Cu is incorporated into the core by cation exchange reaction with the Group 11 element.

The Group 11 element may be Ag, the Group 13 element may be at least one of In, Ga or Al, and the Group 16 element may be at least one of S, Se or Te. The core may include a tetragonal crystal structure of Group I-III-VI compound.

The shell may include an inner shell including Ga as a cation and at least one of S or Se as an anion; and an outer shell on the inner shell, the outer shell including Zn as a cation and at least one of S or Se as an anion.

The core may be (Cuₓ,Ag₍₁₋ₓ₎)—(In_{y},Ga_{(1-y)})—(S_{z},Se_{(1-z)}) where 0<x≤1, 0≤y<1, 0<z≤1.

Another quantum dot according to the present disclosure includes a core/an inner shell/an outer shell, wherein the core is (Cuₓ,Ag₍₁₋ₓ₎—(In_{y},Ga_{(1-y)})—(S_{z},Se_{(1-z)}), the inner shell is GaS_{w}Se_{(1-w)}, and the outer shell is ZnSₜSe₍ₗ₋ₜ₎, where 0<x≤1, 0<y<1, 0<z≤1, 0≤w≤1, 0≤t≤1.

A method for fabricating quantum dots according to the present disclosure includes the steps of (a) synthesizing a primary core including Group 11 element other than Cu, Group 13 element and Group 16 element; (b) synthesizing a secondary core by adding Cu to the primary core through cation exchange; and (c) forming a shell on the secondary core.

In the step of synthesizing the secondary core, the Cu may be a monovalent or divalent metal salt, and may be supplied from at least one of copper fluoride, copper chloride, copper bromide, copper iodide, copper acetate, copper nitrate, copper cyanide or copper acetylacetonate.

A precursor of the Group 11 element and a precursor of Group 13 element may include at least one of silver fluoride, silver chloride, silver bromide, silver iodide (AgI), silver acetate, silver nitrate, silver cyanide, silver acetylacetonate, indium fluoride, indium chloride, indium bromide, indium iodide (InI₃), indium acetate, indium acetylacetonate, gallium fluoride, gallium chloride (GaCl₃), gallium bromide, gallium iodide (GaI₃) or gallium acetylacetonate.

The step of synthesizing the primary core may include the step of mixing AgI, InI₃, GaI₃ and a solvent, adding a precursor of S and raising a temperature to cause reaction, lowering the temperature and adding TOP to form the primary core in a mixed solution, and the step of synthesizing the secondary core may include the step of further lowering the temperature of the mixed solution including the primary core and adding a precursor of the Cu to cause reaction.

In an embodiment, the step (c) is a step of forming a Ga based single shell on the secondary core, and may include the steps of purifying the synthesized secondary core; and mixing the purified secondary core, GaCl₃, S and a solvent, raising the temperature to cause reaction and lowering the temperature to carry out surface treatment with ZnCl₂-TOP and DDT.

In another embodiment, the step (c) is a step of forming a Zn based single shell on the secondary core, and may include the steps of purifying the synthesized secondary core; and mixing the purified secondary core, S and a solvent, raising the temperature to cause reaction with an addition of a solution in which zinc acetate[Zn(OAc)₂] is dissolved in oleic acid to form Zn-oleate, and lowering the temperature.

In still another embodiment, the step (c) is a step of forming a double shell on the secondary core, and may include the steps of purifying the synthesized secondary core; mixing the purified secondary core with GaCl₃, S and a solvent, raising the temperature to cause reaction and lowering the temperature to carry out surface treatment with ZnCl₂-TOP and DDT to form a GaSₓ shell on the secondary core; purifying the secondary core combined with the GaSₓ shell; and mixing the purified secondary core combined with the GaSₓ shell, S and a solvent, raising the temperature to cause reaction with an addition of a solution in which zinc acetate[Zn(OAc)₂] is dissolved in oleic acid to form Zn-oleate, and lowering the temperature to form a ZnS shell on the GaSₓ shell.

The method may, between the step (a) and the step (b), further include the step of forming a shell on the primary core.

A composition of the shell on the primary core and a composition of the shell on the secondary core may overlap in at least part.

In the step (b), the Cu may fully substitute the Group 11 element other than Cu.

### Advantageous Effects

According to the present disclosure, it may be possible to provide I-III-VI based quantum dots added with Cu with band-edge emission in the visible light region and the infrared region.

The quantum dots fabricated according to the present disclosure may be supplied with Cu through cation exchange, not from the beginning, and the quantum dots synthesized through this method may have core/shell structure including GaSₓ shell, thereby enhancing emission efficiency.

The quantum dots fabricated according to the present disclosure may be synthesized as core/shell quantum dots with band-edge emission by the supply of Cu through cation exchange, not from the beginning, and ZnS shelling.

The emission wavelength of the quantum dots fabricated according to the present disclosure may be adjusted by changing the ratio between Group 13 elements synthesized at the early stage, for example, the In/Ga ratio, and the emission wavelength may be adjusted by adding Group 16 element, for example, Se.

According to the present disclosure, it may be possible to obtain quantum dots with dominant band-edge emission for use as display materials.

The quantum dots of the present disclosure may be I-III-VI based quantum dots added with Cu, and have narrow full width at half maximum and particle size of 3.0 nm or more that is larger in size than red InP quantum dots.

### BRIEF DESCRIPTION OF THE DRAWINGS

FIG. 1 is a diagram of a quantum dot according to an embodiment of the present disclosure.

FIG. 2 is a diagram of a quantum dot according to another embodiment of the present disclosure.

FIG. 3 is a flowchart of a method for fabricating quantum dots according to an embodiment of the present disclosure.

FIG. 4 is a flowchart of a method for fabricating quantum dots according to another embodiment of the present disclosure.

FIG. 5 is a diagram showing a quantum dot in each step of the fabrication method of FIG. 4.

FIG. 6 shows emission characteristics evaluation results of Comparative Example 1 core and Examples 1 to 4 core.

FIG. 7 is a transmission electron microscopy (TEM) image of Comparative Example 1 core and Examples 2 and 3 core.

FIG. 8 shows x-ray diffraction (XRD) patterns of Comparative Example 1 core and Examples 2 and 3 core.

FIG. 9 shows emission characteristics evaluation results of Comparative Example 1/GaSₓ shell and Examples 1 to 4/GaSₓ shell.

FIG. 10 shows emission characteristics evaluation results of Comparative Example 1/ZnS shell and Example 2/ZnS shell.

FIG. 11 shows emission characteristics evaluation results of Examples 2, 5 and 6 core and GaSₓ shell.

FIG. 12 shows emission characteristics evaluation results of Comparative Examples 2 and 3 core and GaSₓ shell.

FIG. 13 shows emission characteristics evaluation results of Comparative Example 4 and Example 7 core and GaSₓ shell.

FIG. 14 shows emission characteristics evaluation results of Comparative Example 1/GaSₓ shell and Example 8/multi-shell.

### BEST MODE

The accompanying drawings illustrate the exemplary embodiments of the present disclosure, and together with the foregoing detailed description, serve to provide a better understanding of the technical aspect of the present disclosure, and thus the present disclosure should not be construed as being limited to the accompanying drawings.

Quantum dots according to the present disclosure and a method for fabricating the same will be described in detail with reference to the accompanying drawings. The accompanying drawings are provided by way of illustration to convey the technical aspect of the present disclosure fully and completely. Accordingly, the present disclosure is not limited to the accompanying drawings and may be embodied in any other form. It is obvious that the technical and scientific terms as used herein have the meaning of the terms commonly understood by those skilled in the art unless defined otherwise. Additionally, a certain detailed description of known functions and elements that may unnecessarily obscure the subject matter of the present disclosure in the following description and the accompanying drawings is omitted.

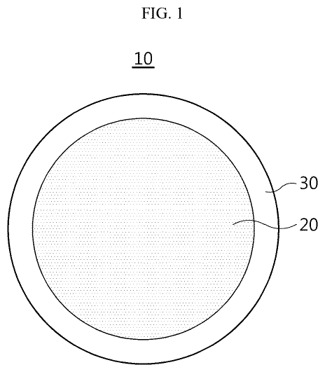

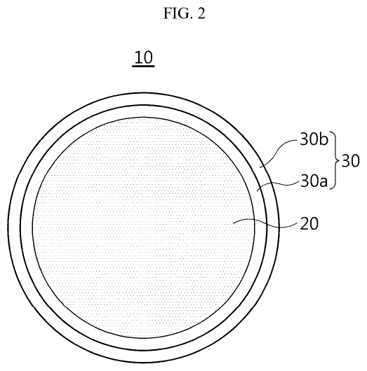

FIG. 1 is a diagram of a quantum dot according to an embodiment of the present disclosure. FIG. 2 is a diagram of a quantum dot according to another embodiment of the present disclosure.

Referring to FIGS. 1 and 2, the quantum dot 10 of the present disclosure includes a core 20, and a shell 30 on the core 20.

The core 20 includes Cu, Group 13 element and Group 16 element. For example, the Group 13 element may include at least one of In, Ga or Al, and the Group 16 element may include at least one of S, Se or Te. In such a case, for example, the core 20 may have composition of Cu—In—Ga—S.

As another example, the core 20 may optionally further include Group 11 element other than Cu. For example, the Group 11 element may be Ag. Accordingly, for example, the core 20 may have composition of Cu—Ag—In—Ga—S.

The important thing is that the quantum dot 10 exhibits band-edge emission in the visible light region and the infrared region.

The quantum dot 10 may be fabricated by the unique fabrication method of the present disclosure, and the Cu may be incorporated into the core 20 by cation exchange reaction with the Group 11 element. The Cu may be, for example, added after the formation of Ag based Group 11-Group 13-Group 16 multicomponent compound quantum dots, not from the beginning of synthesis and supplied through cation exchange.

Group I element on IUPAC periodic table of elements may refer to Group 11 element.

Group III element on IUPAC periodic table of elements may refer to Group 13 element.

Group VI element on IUPAC periodic table of elements may refer to Group 11 element.

The quantum dot 10 may include a tetragonal crystal structure of Group I-III-VI compound.

In the quantum dot 10, the Group 11 element may include at least one of Ag or Au, the Group 13 element may include at least one of In, Ga or Al, and the Group 16 element may include at least one of S, Se or Te.

For example, the core 20 may include Cu, Ag (Group 11 element), In and Ga (Group 13 element) and S (Group 16 element). The core 20 may include Ag—Ga—S (shortened to AGS) tetragonal, Ag—In—S (shortened to AIS) tetragonal, Cu—In—S (shortened to CIS) tetragonal and Cu—Ga—S (shortened to CGS) tetragonal crystal structure. For example, Ag based Group 11-Group 13-Group 16 multicomponent compound quantum dots may include AGS tetragonal and AIS tetragonal crystal structure, and after cation exchange that changes to Cu based crystal structure, may include CIS tetragonal and CGS tetragonal crystal structure.

As another example, the core 20 may include Cu and Ag (Group 11 element), In and Ga (Group 13 element) and S and Se (Group 16 element).

The core 20 may include Cu and Ag together. The core 20 may include In or Ga, and may include In and Ga together. Additionally, the core 20 may further include other Group 13 element such as Al. The core 20 may include S or Se and may include S and Se together.

The core 20 may include Cu, with no Ag, Group 13 element and Group 16 element.

The emission wavelength of the quantum dot 10 may be adjusted by changing a ratio between Group 13 element and Group 11 element synthesized at the early stage and a ratio between Group 13 elements, for example, an In/Ga ratio, and the emission wavelength may be adjusted by adding Group 16 element, for example, Se.

To sum, the core 20 may be (Cuₓ,Ag₍₁₋ₓ₎)—(In_{y},Ga_{(1-y)})—(S_{z},Se_{(1-z)}), where 0<x≤1, 0≤y<1, 0<z≤1. Here, the emission wavelength may be adjusted by adjusting the size of x, y and z.

The quantum dot 10 may further include ligands on the surface of the core 20. The ligands may be thiols such as 1-dodecanethiol (DDT). In addition to the DDT, the ligands may be alkyl thiols such as 1-octanethiol (OTT), 1-hexadecanethiol or decanethiol. Additionally, the ligands may be at least one of amines, phosphines or metal salts.

Specifically, the ligands may include at least one of amines such as 1-butanethiol, 1-hexanethiol, OTT, 1-undecanethiol, decanethiol, DDT, 1-hexadecanethiol, 1-octadecanethiol, amylamine, butylamine, hexylamine, heptylamine, octylamine, nonylamine, decylamine, didecylamine, tetradecylamine, hexadecylamine, octadecylamine, oleylamine (OLA), trihexylamine, trioctylamine (TOA) and tridodecylamine, tributylphosphine oxide, tributylphosphine, trioctylphosphine oxide (TOPO), trioctylphosphine (TOP), ZnF₂, ZnCl₂, ZnBr₂, ZnI₂, GaF₃, GaCl₃, GaBr₃, GaI₃, AlF₃, AlCl₃, AlBr₃ or AlI₃.

Further, the ligands may be derived from a solvent used in the fabrication method. Here, the solvent may include at least one of 1-octadecene (ODE), OLA, oleic acid (OA), dodecylamine, TOA or TOP.

The shell 30 may include Ga or Zn.

The quantum dot 10 may be supplied with Cu through cation exchange, not from the beginning, and the quantum dot 10 synthesized through this method may have the enhanced emission efficiency in the core/shell structure including GaSₓ shell as the shell 30.

Likewise, the quantum dot 10 may be synthesized as core/shell quantum dots with band-edge emission by supplying Cu through cation exchange, not from the beginning, and applying ZnS shell as the shell 30.

The quantum dot 10 may be 3 nm or more in size and exhibit band-edge emission in the visible light region and the infrared region. The size of the quantum dot 10 may be, for example, from 3.5 nm to 6 nm. For example, the average size may be 5.5 nm. The fabrication method according to the present disclosure as described below is suitable for the synthesis of the core 20 of the aforementioned size. The size of the quantum dot 10 equals the sum of the core 20 and the thickness of the shell 30.

After the shelling 30, quantum efficiency may increase compared to the core 20. Additionally, after the shelling 30, the full width at half maximum may be 60 nm or less.

The quantum dot 10 may enhance band-edge emission and reduce defect state emission by incorporating the Cu into the core 20 by cation exchange reaction with the Group 11 element. Accordingly, the quantum dot 10 may have a band-edge emission area ratio of 90% or more on the entire PL spectrum of the core 20. By the high band-edge emission area ratio, the quantum dot 10 has narrow full width at half maximum. The known I-III-VI based quantum dots include various defects therein, and exhibit various emission through the defects. That is, defect state emission is dominated, and the emission spectrum is broad. It can be only used in lighting applications. In contrast, the quantum dot 10 according to the present disclosure may exhibit the emission spectrum in a desired color, for example, red at the very narrow full width at half maximum due to the overwhelmingly dominant band-edge emission, and thus can be used in display applications.

According to the present disclosure, it may be possible to form the core 20 exhibiting a very low level of defect state emission, especially Cu—Ag—In—Ga—S core, and synthesize the quantum dot 10 having high color purity after the core/shell step.

The shell 30 may be a composition of two or more-component system including at least one of Zn, Al, Ga or In and at least one of S or Se. For example, the shell 30 may include Ga or Zn as a cation and at least one of S or Se as an anion. For example, the shell 30 may include Ga and S. Additionally, the shell 30 may further include Zn.

The shell 30 may be a multicomponent single or multi shell structure. The multi shell may be double or triple. When the shell 30 is a double or triple or multi shell, the shell 30 may have a gradual increase in band gap in the outward direction, i.e., as it goes farther away from the core 20. The shell 30 has high passivation effect. Accordingly, the PL and quantum efficiency of the quantum dot 10 may be improved.

FIG. 1 shows a single shell 30, and FIG. 2 shows a double shell 30. The double shell 30 may include an inner shell 30a and an outer shell 30b on the inner shell 30a, wherein the inner shell 30a may include, for example, Ga as a cation and at least one of S or Se as an anion, and the outer shell 30b may include, for example, Zn as a cation and at least one of S or Se as an anion.

To sum, the quantum dot 10 shown in FIG. 2 may be a quantum dot including the core 20/the inner shell 30a/the outer shell 30b, wherein the core 20 may be (Cuₓ,Ag₍₁₋ₓ₎)—(In_{y},Ga_{(1-y)})—(S_{z},Se_{(1-z)}), the inner shell 30a may be GaS_{w}Se_{(1-w)}, and the outer shell 30b may be ZnSₜSe₍ₗ₋ₜ₎, where 0<x≤1, 0≤y<1, 0<z≤1, 0≤w≤1, 0≤t≤1. The most common composition of the core 20/the inner shell 30a/the outer shell 30b may be Cu—Ag—In—Ga—S/GaSₓ/ZnS.

The quantum dot 10 including the shell 30 may have the band-edge emission area ratio of 95% or more on the entire PL spectrum. Due to further including the shell 30, the band-edge emission area ratio may increase compared to the core 20.

The quantum efficiency of the quantum dot 10 including the shell 30 may be 85% or more. Due to further including the shell 30, the quantum efficiency of the quantum dot 10 may be higher than the quantum efficiency of the core 20. The quantum efficiency of the quantum dot 10 is a minimum of 85%, and the quantum efficiency of the quantum dot 10 may be increased through band gap engineering of the shell 30.

Cu, optionally Group 11 element, Group 13 element and Group 16 element may form a homogeneous compound from the center of the core 20 to the surface of the core 20.

As another example, the core 20 may include a first part on the inside including Cu, optionally Group 11 element, Group 13 element and Group 16 element, and a second part covering the first part and having a higher Cu concentration than the first part. Here, as an example, the first part may be Ag—In—Ga—S and the second part may be Cu—Ag—In—Ga—S. As another example, each of the first part and the second part may be equally Cu—Ag—In—Ga—S, but the Cu concentration in the second part may be higher than the Cu concentration in the first part.

As described below in the fabrication method, after the synthesis of the primary core including Group 11 element other than Cu, Group 13 element and Group 16 element, Cu is added to the primary core through cation exchange, and the cation exchange starts from the surface of the primary core and the reaction proceeds toward the center of the primary core. When the cation exchange is not thoroughly completed to the center of the primary core, the core 20 may look like it is divided into the first part and the second part by a Cu concentration difference. Additionally, a Cu concentration gradient may be created in the second part.

The ratio of Group 11 element: Group 13 element in the core 20, the ratio of Group 13 elements in the core 20, for example, the composition ratio between In and Ga may be adjusted for the quantum dot 10 to emit red visible light. Along with adjusting the composition ratio between Group 11 element and Group 13 element, adjusting the composition ratio between Group 13 elements, for example, In and Ga is unique to the present disclosure. In this case, the emission center wavelength of the core 20 may be 590 nm or more. The center wavelength corresponds to red and infrared region emission.

In particular, when Cu is added to the primary core including Group 11 element other than Cu, Group 13 element and Group 16 element, the emission wavelength may be red-shifted, and thus it may be possible to adjust the emission wavelength in the red and infrared region by changing the amount of Cu at the set composition ratio of Group 11 element other than Cu and Group 13 element. The amount of Cu may correspond to a molar ratio of 0.05 or more (Cu/Group 11 element molar ratio) to the initial Group 11 element, Ag.

The quantum dot 10 may exhibit band-edge emission in the red region with the full width at half maximum of 70 nm or less. The quantum dot 10 may exhibit band-edge emission in the infrared region with the full width at half maximum of 80 nm or less.

The quantum dot 10 may be used as display materials. The quantum dot 10 may be applied as a photoconversion layer (a color filter for display) on a blue LED. The quantum dot 10 may be 3.0 nm or more in size that is larger than red InP quantum dots, thereby achieving sufficient light absorption.

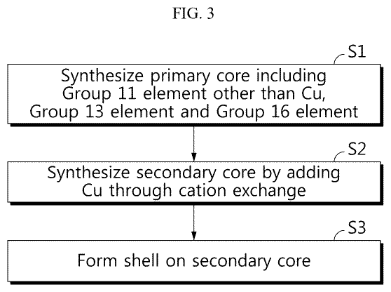

FIG. 3 is a flowchart of a method for fabricating quantum dots according to an embodiment of the present disclosure.

Referring to FIG. 3, first, the primary core including Group 11 element other than Cu, Group 13 element and Group 16 element is synthesized (step S1).

In the step S1 of synthesizing the primary core, a precursor of Group 11 element and a precursor of Group 13 element may include at least one of silver fluoride, silver chloride, silver bromide, silver iodide (AgI), silver acetate, silver nitrate, silver cyanide, silver acetylacetonate, indium fluoride, indium chloride, indium bromide, indium iodide (InI₃), indium acetate, indium acetylacetonate, gallium fluoride, gallium chloride (GaCl₃), gallium bromide, gallium iodide (GaI₃) or gallium acetylacetonate. In particular, a halide based metal salt precursor may be used.

The halide based metal salt precursor may include precursors of Group 11 elements and precursors of Group 13 elements, and the Group 11 element and the Group 13 element of the halide based metal salt precursor may be synthesized as precursors in a powder state or a dissolved state in solvent.

The precursor of Group 11 element and the precursor of Group 13 element may include, for example, at least one of AuF, AuCl, AuBr, AuI, CuF, CuCl, CuBr, CuI, AgF, AgCl, AgBr, AgI, InF₃, InCl₃, InBr₃, InI₃, GaF₃, GaCl₃, GaBr₃ or GaI₃.

The Group 16 element of the Group 16 precursor may be injected in a dissolved state in solvent.

The solvent may include at least one of ODE, OLA, OA, dodecylamine, TOA or TOP.

For example, the step S1 of synthesizing the primary core may include mixing AgI, InI₃ and GaI₃ with the solvent, adding a precursor of S, raising the temperature to cause reaction, lowering the temperature, and adding TOP to form the primary core in the mixed solution. The precursor of S may include thiol based ligands such as DDT and sulfur. In addition to DDT, the precursor of S may include alkylthiols such as octanethiol, hexadecanethiol, decanethiol.

Specifically, the step S1 of synthesizing the primary core includes mixing AgI, InI₃ and GaI₃ with the solvent and adding the precursor of S to prepare the mixed solution, and heating up the mixed solution. In this process, degassing and N₂ substitution may be performed. The heating up may be performed in multiple steps, and degassing may be performed at low temperature, followed by heating up to the reaction temperature, causing reaction. The synthesis of the primary core may be completed within 10 minutes, for example, 5 minutes, after heating up to the reaction temperature.

Subsequently, the temperature of the mixed solution may be lowered down and TOP may be added. The TOP is an additional ligand material and protects the primary core surface and removes defects that may exist on the primary core surface. In addition to TOP, OTT or DDT may be used. This step is performed to improve efficiency and stability of the primary core through additional ligand adsorption. This step may be performed for about 20 minutes.

Subsequently, Cu is added to the primary core through cation exchange to synthesize the secondary core (step S2). This step may be performed for about 20 minutes.

In the step S2 of synthesizing the secondary core, the Cu may include monovalent or divalent metal salts, and may be supplied from at least one of copper fluoride, copper chloride, copper bromide, copper iodide, copper acetate, copper nitrate, copper cyanide or copper acetylacetonate. A precursor of Cu may include, for example, at least one of CuF, CuCl, CuBr, CuI or Cu(OAc).

The step S2 of synthesizing the secondary core may include further lowering the temperature of the mixed solution including the primary core and adding the precursor of Cu, causing reaction.

Here, it should be noted that the Cu is incorporated into the primary core by the cation exchange reaction with the Group 11 element to form the secondary core. In this instance, when the Cu fully substitutes the Group 11 element other than Cu, the Group 11 element present in the primary core at the early stage may not remain in the secondary core. Accordingly, the composition of the secondary core essentially includes Cu, Group 13 element and Group 16 element, and optionally, may or may not include Group 11 element other than Cu. It should be noted that the Group 11 element other than Cu is further included during the fabrication process, but after the fabrication, the Group 11 element may not remain in the core.

Subsequently, the shell is formed on the secondary core (step S3). Accordingly, the quantum dot 10 including the shell 30 on the core 20 may be obtained.

Here, after separating the secondary core from the mixed solution, the shelling step is performed. For example, the secondary core in the mixed solution is purified after precipitation using a polar solvent. The polar solvent may include ethanol, acetone, etc. The purification may be performed using a hexane/ethanol solvent using a centrifugal separator (9000 rpm, 10 min). The secondary core is re-dispersed in a non-polar solvent and the precursor for forming the shell 30 is injected to form the shell 30. Here, the non-polar solvent may include hexane, octane, toluene, chloroform, ODE, OLA. The Ga precursor for forming the shell 30 may be GaCl₃, and the Zn precursor may be ZnCl₂.

More specifically, the step S3 of forming the shell on the secondary core may include forming the shell 30 including at least one of Group 12 element or Group 13 element and at least one of Group 16 elements on the secondary core.

For example, GaSₓ shell may be formed by injecting the Ga precursor and the precursor of S, causing reaction at the temperature of 200° C. or more, for example, 240° C. for 2 hours, lowering the temperature to 200° C. or less, and adding the additional ligand material such as TOP or DDT to protect the surface of the core/shell quantum dots (step S25). The Ga precursor may be GaCl₃, and the precursor of S may be sulfur.

The shell may be formed with any other composition than GaSₓ, and may be formed by applying a suitable shell stock solution onto the core. Additionally, the step of forming the shell may be performed consecutively two or more times. In this instance, at least one of the type, concentration or reaction temperature of the shell stock solution and the time may be different for each step. In the second reaction, the temperature may be higher or the time may be longer.

Describing the step S3 in more detail, for the step of forming the Ga based single shell on the secondary core, the step S3 may include purifying the synthesized secondary core; and mixing the purified secondary core, GaCl₃, S and the solvent, raising the temperature to cause reaction, and lowering the temperature to carry out surface treatment with ZnCl₂-TOP and DDT.

As another example, the step S3 may be the step of forming the Zn based single shell on the secondary core, and may include purifying the synthesized secondary core; and mixing the purified secondary core, S and the solvent, raising the temperature to cause reaction with an addition of a solution in which zinc acetate[Zn(OAc)₂] is dissolved in oleic acid to form Zn-oleate, and then lowering the temperature.

As still another example, the step S3 may be the step of forming the double shell on the secondary core, for example, the shell including the inner shell 30a and the outer shell 30b like the quantum dot 10 shown in FIG. 2. The step S3 may include purifying the synthesized secondary core; mixing the purified secondary core, GaCl₃, S and the solvent, raising the temperature to cause reaction, and lowering the temperature to carry out surface treatment with ZnCl₂-TOP and DDT to form GaSₓ shell on the secondary core; purifying the secondary core combined with the GaSₓ shell; and mixing the purified secondary core combined with the GaSₓ shell, S and the solvent, raising the temperature to cause reaction with an addition of a solution in which zinc acetate[Zn(OAc)₂] is dissolved in oleic acid to form Zn-oleate, and lowering the temperature to form the ZnS shell on the GaSₓ shell.

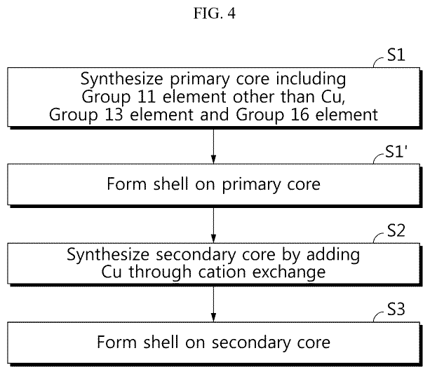

Subsequently, FIG. 4 is a flowchart of the method for fabricating quantum dots according to another embodiment of the present disclosure.

Compared to the fabrication method of FIG. 3, the fabrication method of FIG. 4 further includes the step (step S1′) of forming the shell on the primary core between the step (step S1) of synthesizing the primary core and the step (step S2) of synthesizing the secondary core.

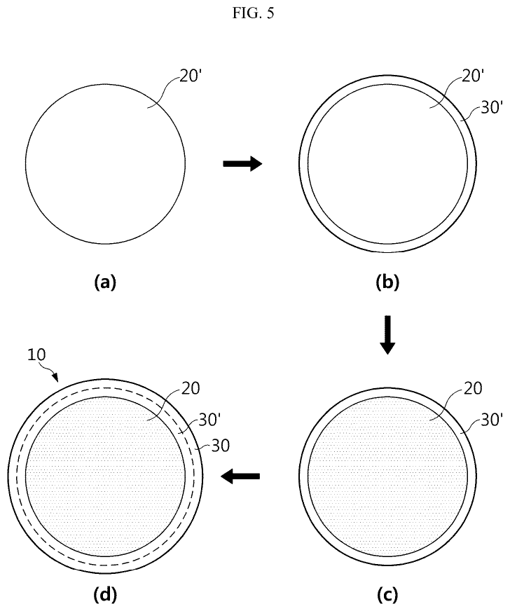

FIG. 5 shows the quantum dot in each step of the fabrication method of FIG. 4.

Referring to FIGS. 4 and 5, the primary core 20′ including Group 11 element other than Cu, Group 13 element and Group 16 element is synthesized (step S1 in FIG. 4, FIG. 5(a)). The primary core 20′ may be, for example, Ag—In—Ga—S.

Subsequently, the shell 30′ is formed on the primary core 20′ (step S1′ in FIG. 4, FIG. 5(b)). The shell 30′ may be formed by the same composition and the same method as the shell 30. For example, the shell 30′ may be GaSₓ.

Subsequently, the secondary core 20 is synthesized by adding Cu to the primary core 20′ through cation exchange (step S2 in FIG. 4, FIG. 5(c)). The secondary core 20 may be, for example, Cu—Ag—In—Ga—S. The Cu supplied from the precursor of Cu may be incorporated by substitution for the Group 11 element in the primary core 20′ via the shell 30′ on the primary core 20′.

Subsequently, the shell 30 is formed on the secondary core 20 (step S3 in FIG. 4, FIG. 5(d)). As described above, the shell 30 may be, for example, GaSₓ and/or ZnS.

The composition of the shell 30′ on the primary core 20′ and the composition of the shell 30 on the secondary core 20 may overlap at least in part. For example, the same is the case with GaSₓ as the shell 30′ and GaSₓ/ZnS as the shell 30. Thus, the shell 30′ and the shell 30 may not be clearly distinguished in the final quantum dot 10, and may be collectively referred to as the shell 30.

Hereinafter, the present disclosure will be described in more detail by describing Experimental Example.

### Experimental Example: Core Synthesis

To form Ag—In—Ga—S core as the primary core, AgI, InI₃, GaI₃, ODE and OLA are put into a 3 neck flask, followed by inert gas substitution, raising the temperature to 120° C. and stirring.

Subsequently, OTT and sulfur (S, mixed with OLA) were injected, followed by raising the temperature (heating up) to 280° C. and causing reaction within 5 minutes. Subsequently, TOP was injected at 180° C., causing reaction for 20 minutes, followed by lowering the temperature to 150° C., adding a Cu solution (CuI-OLA) and causing reaction for 20 minutes to synthesize the secondary core through cation exchange. The formation of the core 20, in particular, Cu—Ag—In—Ga—S core, as shown in FIGS. 1 and 2 is completed.

The core is purified using a polar solvent such as ethanol, and dispersed in ODE for use in the shelling process.

### Experimental Example: Ga Based Shell Formation

The process of forming the shell including Ga may include putting the synthesized core, GaCl₃ and sulfur into a flask containing OLA, causing reaction at 240° C. for 2 hours, and subsequently, carrying out surface treatment for 20 minutes with an addition of DDT and ZnCl₂-TOP solution at 200° C., and lowering the temperature of the reactant solution to room temperature to fabricate quantum dots of core/shell structure including GaSₓ as the shell material.

### Experimental Example: Zn Based Shell Formation

The process of forming the shell including Zn may include putting the synthesized core and sulfur into a flask containing OLA, and dissolving Zn(OAc)₂ in a mixed solution of ODE and OA at 240° C. and injecting. After reaction, the temperature may be lowered to room temperature to fabricate quantum dots of core/shell structure including ZnS as the shell material.

Subsequently, the synthesized quantum dots of core/shell structure were purified using a polar solvent, and dispersed in hexane to evaluate optical properties. Photoluminescence (PL) was measured at room temperature using PL equipment (Darsa Pro-5200, PSI Co. Ltd.) using a light source 500 W Xenon (Xe) discharge lamp.

### Comparative Example 1 (Ag—In—Ga-Score with No Added Cu and GaSₓ, ZnS Shell)

0.3 mmol of AgI, 0.4 mmol of InI₃, 0.5 mmol of GaI₃, 5 mL of OLA and 5 mL of ODE were used, and S-OLA was injected to carry out synthesis. In Comparative Example 1, the step of adding Cu was removed and the characteristics of pure Ag—In—Ga—S core were evaluated. Additionally, the characteristics of Comparative Example 1 core combined with each of GaSₓ shell and ZnS shell were evaluated.

### Example 1 (Core with 0.05 Mmol of Cu Added and GaSₓ Shell)

0.3 mmol of AgI, 0.4 mmol of InI₃, 0.5 mmol of GaI₃, 5 mL of OLA and 5 mL of ODE were used, and S-OLA was injected to carry out synthesis. Example 1 evaluated the characteristics of core/shell quantum dots including Cu—Ag—In—Ga—S core with a total of 0.05 mmol of Cu added by injecting 0.5 mL of 0.1M Cu-OLA solution at the step of adding Cu and GaSₓ shell.

The composition ratio between Ag, In and Ga is the same as that of Comparative Example 1, only different in that Cu is added by cation exchange.

### Example 2 (Core with 0.1 Mmol of Cu Added and GaSₓ, ZnS, GaSₓ/ZnS Shell)

0.3 mmol of AgI, 0.4 mmol of InI₃, 0.5 mmol of GaI₃, 5 mL of OLA and 5 mL of ODE were used, and S-OLA was injected to carry out synthesis. Example 2 evaluated the characteristics of Cu—Ag—In—Ga—S core with a total of 0.1 mmol of Cu added by injecting 1 mL of 0.1M Cu-OLA solution at the step of adding Cu. Additionally, the characteristics of Example 2 core combined with GaSₓ shell, ZnS shell and GaSₓ/ZnS double shell were evaluated.

The amount of Cu in Example 2 is larger than that of Example 1, and the composition ratio between Ag, In and Ga is the same as those of Comparative Example 1 and Example 1.

### Example 3 (Core with 0.3 Mmol of Cu Added and GaSₓ Shell)

0.3 mmol of AgI, 0.4 mmol of InI₃, 0.5 mmol of GaI₃, 5 mL of OLA and 5 mL of ODE were used, and S-OLA was injected to carry out synthesis. Example 3 evaluated the characteristics of core/shell quantum dots including Cu—Ag—In—Ga—S core with a total of 0.3 mmol of Cu added by injecting 3 mL of 0.1M Cu-OLA solution at the step of adding Cu and GaSₓ shell.

The amount of Cu in Example 3 is larger than that of Example 2, and the composition ratio between Ag, In and Ga is the same as that of Example 2.

### Example 4 (Core with 0.5 Mmol of Cu Added and GaSₓ Shell)

0.3 mmol of AgI, 0.4 mmol of InI₃, 0.5 mmol of GaI₃, 5 mL of OLA and 5 mL of ODE were used, and S-OLA was injected to carry out synthesis. Example 4 evaluated the characteristics of the core/shell quantum dots including Cu—Ag—In—Ga—S core with a total of 0.5 mmol of Cu added by injecting 5 mL of 0.1M Cu-OLA solution at the step of adding Cu and GaSₓ shell.

The amount of Cu in Example 4 is larger than that of Example 3, and the composition ratio between Ag, In and Ga is the same as Example 3.

The amount of Cu increases from Example 1 to Example 4.

### Example 5 (Core with 0.1 Mmol of Cu Added and GaSₓ Shell)

0.3 mmol of AgI, 0.3 mmol of InI₃, 0.6 mmol of GaI₃, 5 mL of OLA and 5 mL of ODE were used, and S-OLA was injected to carry out synthesis. Example 5 evaluated the characteristics of core/shell quantum dots including Cu—Ag—In—Ga—S core with a total of 0.1 mmol of Cu added by injecting 1 mL of 0.1M Cu-OLA solution at the step of adding Cu and GaSₓ shell.

The amount of Cu is the same as that of Example 2, but in Example 2, In: Ga is 4:5, while in Example 5, In: Ga is 1:2. That is, Example 5 uses a larger amount of Ga than Example 2.

### Example 6 (Core with 0.1 Mmol of Cu Added and GaSₓ Shell)

0.3 mmol of AgI, 0.45 mmol of InI₃, 0.45 mmol of GaI₃, 5 mL of OLA and 5 mL of ODE were used, and S-OLA was injected to carry out synthesis. Example 6 evaluated the characteristics of core/shell quantum dots including Cu—Ag—In—Ga—S core with a total of 0.1 mmol of Cu added by injecting 1 mL of 0.1M Cu-OLA solution at the step of adding Cu and GaSₓ shell.

The amount of Cu is the same as that of Example 5, but in Example 5, In: Ga is 1:2, while in Example 6, In: Ga is 1:1. That is, Example 6 uses a larger amount of In than Example 5.

### Comparative Example 2 (Core Using 0.4 Mmol of Cu from the Beginning of Reaction without Ag and GaSₓ Shell)

0.4 mmol of CuI, 0.3 mmol of InI₃, 0.6 mmol of GaI₃, 5 mL of OLA and 5 mL of ODE were used to synthesize a core, and the characteristics of core/shell quantum dots including the synthesized core and GaSₓ shell were evaluated. That is, Comparative Example 2 is directed to pure Cu—In—Ga—S core.

### Comparative Example 3 (Core Using Cu and Ag Together from the Beginning of Reaction and GaSₓ Shell)

0.2 mmol of CuI, 0.2 mmol of AgI, 0.3 mmol of InI₃, 0.6 mmol of GaI₃, 5 mL of OLA and 5 mL of ODE were used to synthesize a core, and the characteristics of core/shell quantum dots including the synthesized core and GaSₓ shell were evaluated.

Comparative Example 3 uses Cu, Ag, In and Ga in the same amounts as Example 5, but does not proceed with later addition of Cu by cation exchange.

### Comparative Example 4 (Ag—In—Ga—S—Se Core with No Cu Added and GaSₓ Shell)

0.2 mmol of AgI, 0.45 mmol of InI₃, 0.45 mmol of GaI₃, 5 mL of OLA and 5 mL of ODE were used, and S-OLA and Se-(OTT, OLA) were injected to carry out synthesis, and the characteristics of core/shell quantum dots including Ag—In—Ga—S—Se core and GaSₓ shell were evaluated.

### Example 7 (Ag—In—Ga—S—Se Core with 0.1 Mmol of Cu Added and GaSₓ Shell)

0.2 mmol of AgI, 0.45 mmol of InI₃, 0.45 mmol of GaI₃, 5 mL of OLA and 5 mL of ODE were used, and S-OLA and Se-(OTT, OLA) were injected to carry out synthesis. Example 7 evaluated the characteristics of core/shell quantum dots including Cu—Ag—In—Ga—S—Se core with a total of 0.1 mmol of Cu added by injecting 1 mL of 0.1M Cu-OLA solution at the step of adding Cu and GaSₓ shell.

### Example 8 (5 Step Synthesis Method, Example of Forming Cu—Ag—In—Ga—S/GaS/GaS/ZnS Multi-Shell by Adding Cu to Ag—In—Ga—S/GaS and Applying GaS/ZnS Shell)

0.3 mmol of AgI, 0.4 mmol of InI₃, 0.5 mmol of GaI₃, 5 mL of OLA and 5 mL of ODE were used, and S-OLA was injected to carry out synthesis. Subsequently, the core was purified using a polar solvent such as ethanol, and dispersed in ODE for use in the shelling process.

The process of forming the shell including Ga may include putting the synthesized core, GaCl₃ and sulfur into a flask containing OLA, causing reaction at 240° C. for 2 hours, and subsequently carrying out surface treatment for 20 minutes with an addition of DDT and ZnCl₂-TOP solution at 200° C., and lowering the reactant solution to room temperature to fabricate quantum dots of core/shell structure including GaSₓ as the shell material.

The quantum dots having the core/shell structure are purified and dispersed in ODE, causing reaction at 150° C. under a nitrogen atmosphere for 1 hour with an addition of 1 mL of TOP and 0.1 mmol of CuI powder, and in this process, cation exchange reaction in the core proceeds to form quantum dots of Cu—Ag—In—Ga—S/GaSₓ core/shell structure.

Subsequently, Ga based shell is formed, and then after purification and re-dispersion, Zn based shell is formed. Subsequently, purification was performed and the characteristics of multi-shell quantum dots were evaluated.

TABLE 1 summarizes the optical properties evaluation results of Comparative Example 1 to Example 8.

TABLE 1

| | Emission | Full width at | Quantum |
|---|---|---|---|
| | wavelength | half maximum | efficiency |
| Type of quantum dots | peak (nm) | (nm) | (%) |
| Comparative Example 1 core | 542 | 38 | 28 |
| Comparative Example 1/GaSₓ | 542 | 33 | 79 |
| Comparative Example 1/ZnS | 626 | 188 | 29 |
| Example 1 core | 618 | 64 | 37 |
| Example 1/GaSₓ | 619 | 56 | 69 |
| Example 2 core | 634 | 53 | 32 |
| Example 2/GaSₓ | 626 | 55 | 68 |
| Example 2/ZnS | 623 | 68 | 65 |
| Example 2/GaSₓ/ZnS | 631 | 61 | 79.5 |
| Example 3 core | 629 | 46 | 14 |
| Example 3/GaSₓ | 623 | 51 | 51 |
| Example 4 core | 631 | 49 | 6 |
| Example 4/GaSₓ | 621 | 51 | 54 |
| Example 5 core | 616 | 52 | 31 |
| Example 5/GaSₓ | 608 | 58 | 62 |
| Example 6 core | 646 | 54 | 54 |
| Example 6/GaSₓ | 640 | 56 | 73 |
| Comparative Example 2 core | 717 | 187 | — |
| Comparative Example 2/GaSₓ | 633 | 204 | — |
| Comparative Example 3 core | 639 | 182 | — |
| Comparative Example 3/GaSₓ | 541 | 60 | — |
| Comparative Example 4 core | 617 | 58 | 12 |
| Comparative Example 4/GaSₓ | 617 | 47 | 72 |
| Example 7 core | 712 | 63 | 36 |
| Example 7/GaSₓ | 712 | 77 | 47 |
| Example 8/GaSₓ | 629 | 41.4 | 18 |
| Example 8/GaSₓ/GaSₓ | 626 | 43 | 57.2 |
| Example 8/GaSₓ/GaSₓ/ZnS | 625 | 45.1 | 85.6 |

Compared to Comparative Example 1, emission wavelength peak increases from Example 1 to Example 4 further including Cu. That is, there is a red shift. It is found that quantum efficiency of Examples 1, 2, 5, 6, 7 and 8 is higher than that of Comparative Example 1, and as confirmed in Example 1 to Example 8, the core-shell may reduce the full width at half maximum and increase the quantum efficiency.

It can be seen that compared to Comparative Example 3 without cation exchange, the full width at half maximum of Example 1 to Example 8 is much smaller.

As can be seen from Example 1 to Example 8, emission wavelength peak may be changed through Cu, Ag, In, Ga, S, Se composition ratio adjustment.

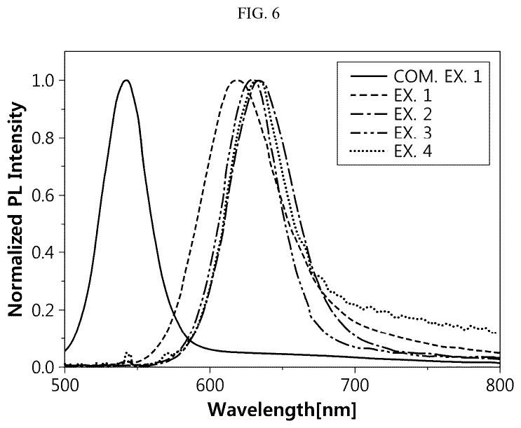

Hereinafter, Examples and Comparative Examples will be described in more detail with reference to FIGS. 6 to 13.

FIG. 6 shows emission characteristics evaluation results of Comparative Example 1 core and Examples 1 to 4 core.

Referring to FIG. 6, as Cu reacts with the core, there is a change in emission peak wavelength from the green region of Comparative Example 1 core (560 nm or less) to the red region of Examples 1 to 4 core (can be seen from TABLE 1). It is confirmed that Examples 1 to 4 core exhibit a very small full width at half maximum of 70 nm or less.

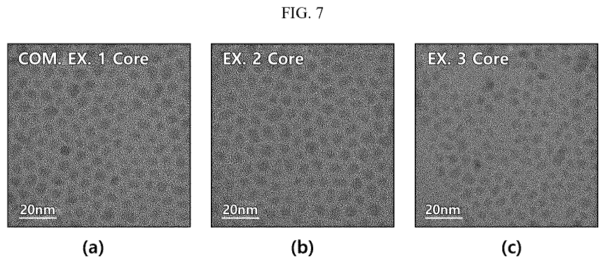

FIG. 7 is a transmission electron microscopy (TEM) image of Comparative Example 1 core and Examples 2 and 3 core.

FIG. 7(a) is a TEM image of Comparative Example 1 core, FIG. 7(b) is a TEM image of Example 2 core, and FIG. 7(c) is a TEM image of Example 3 core. Referring to FIG. 7, it is confirmed that with a change in the amount of Cu added, a change in particle size of the core does not significantly increase or decrease and the size is maintained, and as a result of energy dispersive spectroscopy (EDS) analysis, as shown in TABLE 2 below, with the increasing amount of Cu, the amount of Ag decreases and the amount of Cu increases, and this reveals that cation exchange at Group I position took place.

TABLE 2 shows the EDS results.

TABLE 2

| Element | Comparative | | |
|---|---|---|---|
| (Atomic %) | Example 1 core | Example 2 core | Example 3 core |
| Ag | 12.56 | 7.38 | 3.53 |
| Cu | 0 | 10.33 | 23.28 |
| In | 11.59 | 8.85 | 8.96 |
| Ga | 8.45 | 13.41 | 9.06 |
| S | 67.4 | 60.03 | 55.16 |
| Total | 100 | 100 | 100 |

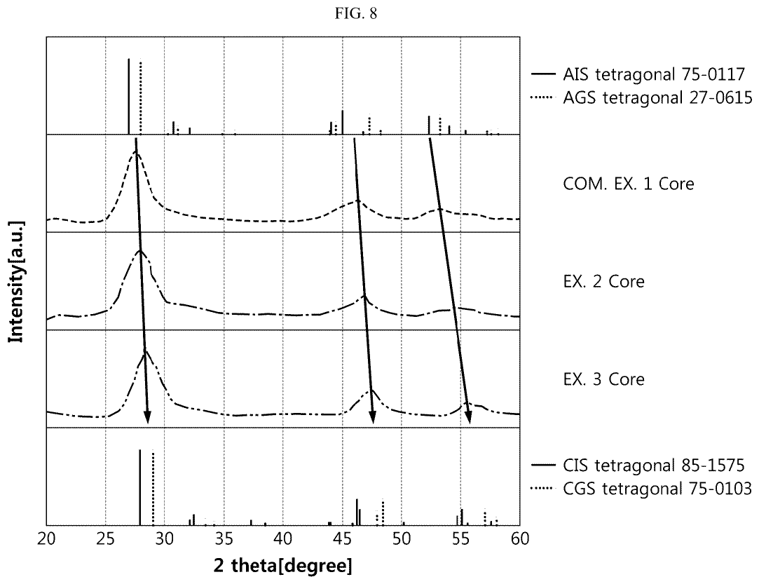

FIG. 8 shows x-ray diffraction (XRD) patterns of Comparative Example 1 core and Examples 2 and 3 core.

Referring to FIG. 8, as a result of determining the crystal structure through the XRD pattern of the core as a function of the amount of Cu added, it is found that Cu-free Ag—In—Ga—S core of Comparative Example 1 shows the similar pattern to AIS tetragonal and AGS tetragonal peak, but as the amount of Cu added increases, the crystal structure is changing closer to CIS tetragonal and CGS tetragonal crystal structure. Through this, in the same way as the previous EDS results, it was confirmed that I-III-VI based quantum dots with band-edge emission may be formed by adding Cu by cation exchange after the formation of Ag—In—Ga—S.

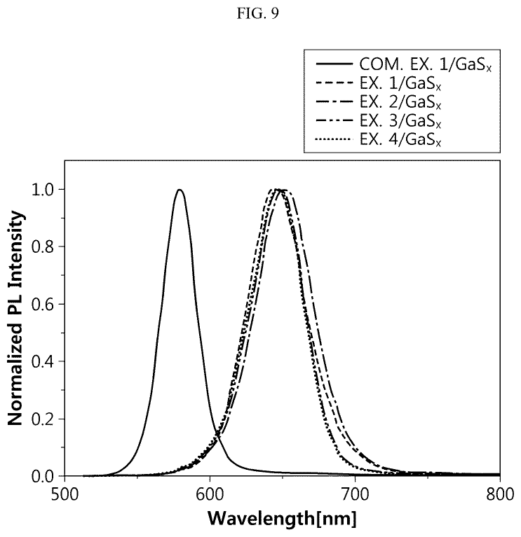

FIG. 9 shows emission characteristics evaluation results of Comparative Example 1/GaSₓ shell and Examples 1 to 4/GaSₓ shell.

Referring to FIG. 9, as a result of applying GaSₓ shell to Comparative Example 1 core and Examples 1 to 4 core, the increased quantum efficiency at the core emission peak wavelength is observed (as can be seen from TABLE 1).

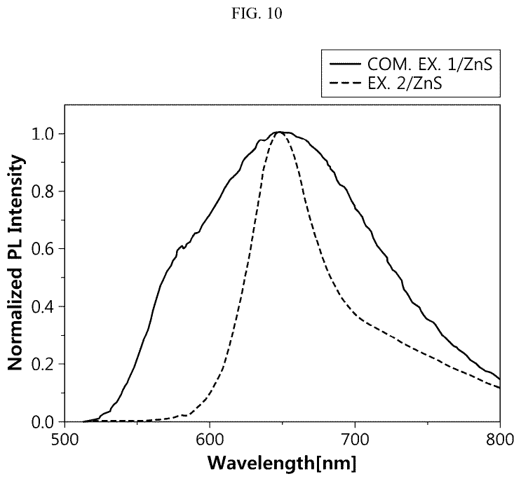

FIG. 10 shows emission characteristics evaluation results of Comparative Example 1/ZnS shell and Example 2/ZnS shell.

As a result of comparing the emission characteristics of Comparative Example 1 and Example 2 after ZnS shelling, it is confirmed that as opposed to the pure Ag based quantum dots of Comparative Example 1, the Cu added quantum dots of Example 2 maintains band-edge emission even after ZnS shelling.

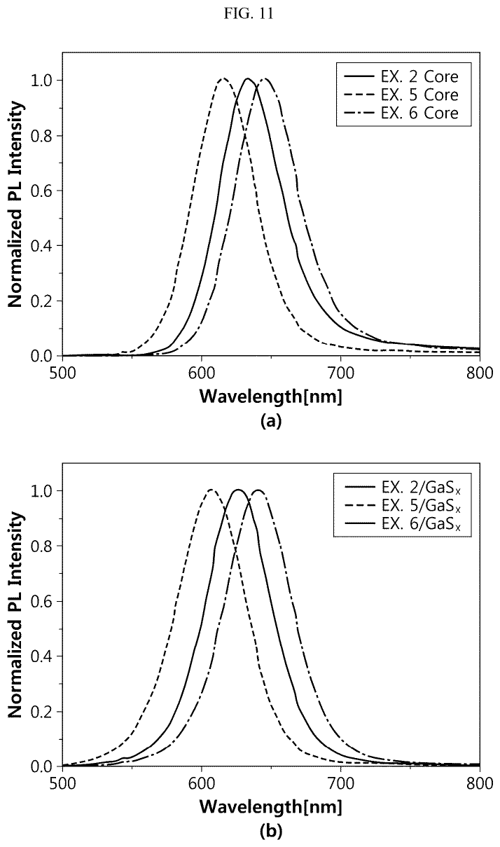

FIG. 11 shows emission characteristics evaluation results of Examples 2, 5 and 6 core and GaSₓ shell.

FIG. 11(a) shows emission characteristics of Examples 2, 5 and 6 core, and FIG. 11(b) shows emission characteristics of quantum dots including Examples 2, 5 and 6 core and GaSₓ shell.

In the same way as Ag based I-III-VI based quantum dots, it is confirmed that the Cu added quantum dots have a change in emission wavelength with a change in In and Ga ratio (can be seen from TABLE 1).

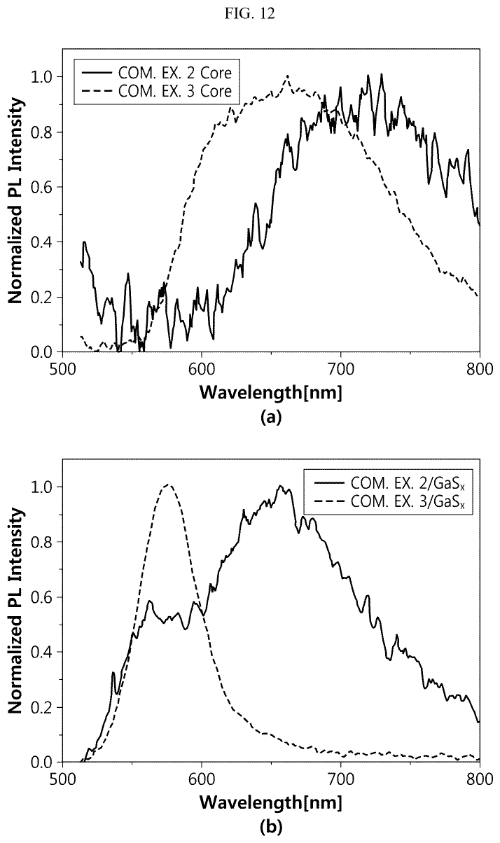

FIG. 12 shows emission characteristics evaluation results of Comparative Examples 2 and 3 core and GaSₓ shell.

FIG. 12(a) shows emission characteristics of Comparative Examples 2 and 3 core, and FIG. 12(b) shows emission characteristics of quantum dots including Comparative Examples 2 and 3 core and GaSₓ shell.

It can be seen that as opposed to adding Cu by cation exchange, Comparative Examples 2 and 3 quantum dots with Cu added from the beginning of reaction exhibit defect emission, not band-edge emission. Comparative Example 3 added with Cu that is mixed with Ag exhibits emission peak at similar wavelengths to Comparative Example 1, and this reveals band-edge emission by Ag. Additionally, it is confirmed that quantum efficiency is also very low.

To sum, the quantum dots including the Ag based core of Comparative Example 1 and Ga as the shell material exhibit band-edge emission but cannot emit red light because they do not include Cu like Example 1 to Example 7. The Cu based core of Comparative Example 2 is not suitable as display materials due to defect emission. The core needs to include Group 13 element other than Cu such as Ag. In addition to Cu, Comparative Example 3 includes Ag, but exhibits similar band-edge emission to Comparative Example 1 with no Cu, and this reveals defect emission of Cu. As opposed to Comparative Example 3, Examples 1 to 7 exhibit dominant band-edge emission by the later addition of Cu through cation exchange.

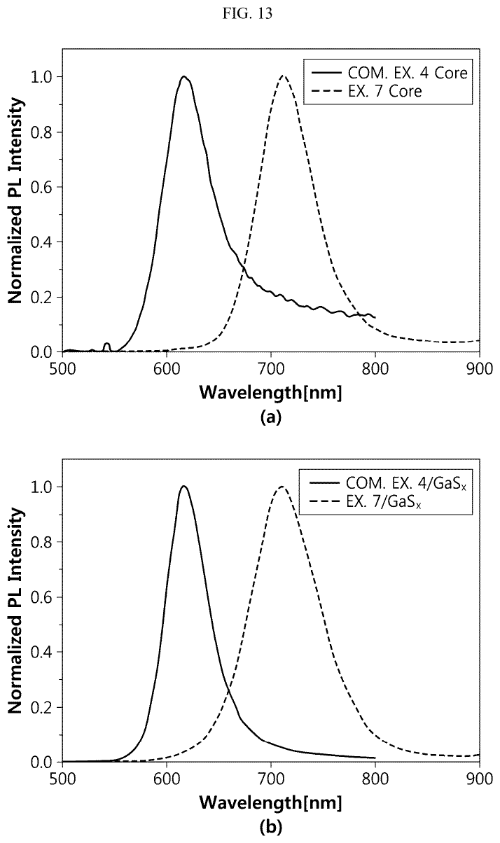

FIG. 13 shows emission characteristics evaluation results of Comparative Example 4 core and Example 7 core and GaSₓ shell.

FIG. 13(a) shows emission characteristics of Comparative Example 4 core and Example 7 core, and FIG. 13(b) shows emission characteristics of quantum dots including Comparative Example 4 core and Example 7 core and GaSₓ shell.

It is confirmed that Example 7 with Cu added to the core of Ag—In—Ga—S—Se quantum dots emitting light in the red region with an addition of Se to Ag—In—Ga—S exhibits emission in the infrared region with narrower band gap in the red region of Ag—In—Ga—S—Se of Comparative Example 4.

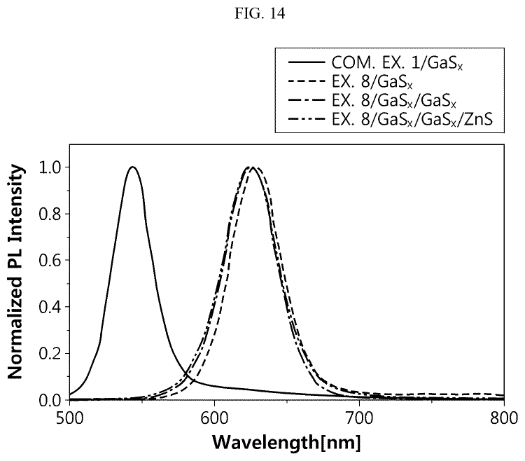

FIG. 14 shows emission characteristics evaluation results of Comparative Example 1/GaSₓ shell and Example 8/multi-shell.

Referring to FIG. 14, it is confirmed that as a result of applying GaSₓ shell/ZnS shell to Comparative Example 1 core and Example 8 core, quantum efficiency remarkably increases in core emission peak wavelength (can be seen from TABLE 1).

This research was supported by the National Research Foundation of Korea (NRF) grant funded by the Korea government (RS-2023-00281346, RS-2024-00411892) and the Technology Innovation Program (20010737) funded by the Ministry of Trade, Industry & Energy (MOTIE, Korea).

While the present disclosure has been hereinabove illustrated and described with respect to particular exemplary embodiments, the present disclosure is not limited thereto and various modifications and changes will be made thereto by those skilled in the art without departing from the technical aspect of the present disclosure.

What is claimed is:

1. Quantum dots, comprising:
a core including Cu, Group 13 element and Group 16 element; and
a shell on the core,
wherein the core optionally further includes Group 11 element other than the Cu, and
wherein the quantum dots exhibit band-edge emission in a visible light region and an infrared region.

2. The quantum dots according to claim 1, wherein the Cu is incorporated into the core by cation exchange reaction with the Group 11 element.

3. The quantum dots according to claim 1, wherein the Group 11 element is Ag, the Group 13 element is at least one of In, Ga or Al, and the Group 16 element is at least one of S, Se or Te.

4. The quantum dots according to claim 1, wherein the core includes a tetragonal crystal structure of Group I-III-VI compound.

5. The quantum dots according to claim 1, wherein the shell includes Ga or Zn as a cation, and at least one of S or Se as an anion.

6. The quantum dots according to claim 1, wherein the shell includes:
an inner shell including Ga as a cation and at least one of S or Se as an anion; and
an outer shell on the inner shell, the outer shell including Zn as a cation and at least one of S or Se as an anion.

7. The quantum dots according to claim 1, wherein the core is (Cuₓ,Ag₍₁₋ₓ₎)—(In_{y},Ga_{(1-y)})—(S_{z},Se_{(1-z)}),
wherein 0<x≤1, 0≤y<1, 0<z≤1.

8. Quantum dots comprising:
a core/an inner shell/an outer shell,
wherein the core is (Cuₓ,Ag₍₁₋ₓ₎—(In_{y},Ga_{(1-y)})—(S_{z},Se_{(1-z)}),
wherein the inner shell is GaS_{w}Se_{(1-w)},
wherein the outer shell is ZnSₜSe₍ₗ₋ₜ₎, and
wherein 0<x≤1, 0≤y<1, 0<z≤1, 0≤w≤1, 0≤t≤1.

9. A method for fabricating quantum dots, comprising the steps of:
(a) synthesizing a primary core including Group 11 element other than Cu, Group 13 element and Group 16 element;
(b) synthesizing a secondary core by adding Cu to the primary core through cation exchange; and
(c) forming a shell on the secondary core.

10. The method for fabricating the quantum dots according to claim 9, wherein in the step of synthesizing the secondary core, the Cu is a monovalent or divalent metal salt, and is supplied from at least one of copper fluoride, copper chloride, copper bromide, copper iodide, copper acetate, copper nitrate, copper cyanide or copper acetylacetonate.

11. The method for fabricating the quantum dots according to claim 9, wherein a precursor of the Group 11 element and a precursor of Group 13 element include at least one of silver fluoride, silver chloride, silver bromide, silver iodide (AgI), silver acetate, silver nitrate, silver cyanide, silver acetylacetonate, indium fluoride, indium chloride, indium bromide, indium iodide (InI₃), indium acetate, indium acetylacetonate, gallium fluoride, gallium chloride (GaCl₃), gallium bromide, gallium iodide (GaI₃) or gallium acetylacetonate.

12. The method for fabricating the quantum dots according to claim 9, wherein the step of synthesizing the primary core comprises the step of mixing AgI, InI₃, GaI₃ and a solvent, adding a precursor of S and raising a temperature to cause reaction, lowering the temperature and adding TOP to form the primary core in a mixed solution, and
wherein the step of synthesizing the secondary core comprises the step of further lowering the temperature of the mixed solution including the primary core and adding a precursor of the Cu to cause reaction.

13. The method for fabricating the quantum dots according to claim 9, wherein the step (c) is a step of forming a Ga based single shell on the secondary core,
wherein the step (c) comprises the steps of:
purifying the synthesized secondary core; and
mixing the purified secondary core, GaCl₃, S and a solvent, raising the temperature to cause reaction and lowering the temperature to carry out surface treatment with ZnCl₂-TOP and DDT.

14. The method for fabricating the quantum dots according to claim 9, wherein the step (c) is a step of forming a Zn based single shell on the secondary core,
wherein the step (c) comprises the steps of:
purifying the synthesized secondary core; and
mixing the purified secondary core, S and a solvent, raising the temperature to cause reaction with an addition of a solution in which zinc acetate[Zn(OAc)₂] is dissolved in oleic acid to form Zn-oleate, and lowering the temperature.

15. The method for fabricating the quantum dots according to claim 9, wherein the step (c) is a step of forming a double shell on the secondary core,
wherein the step (c) comprises the steps of:
purifying the synthesized secondary core;
mixing the purified secondary core with GaCl₃, S and a solvent, raising the temperature to cause reaction and lowering the temperature to carry out surface treatment with ZnCl₂-TOP and DDT to form a GaSₓ shell on the secondary core;
purifying the secondary core combined with the GaSₓ shell; and
mixing the purified secondary core combined with the GaSₓ shell, S and a solvent, raising the temperature to cause reaction with an addition of a solution in which zinc acetate[Zn(OAc)₂] is dissolved in oleic acid to form Zn-oleate, and lowering the temperature to form a ZnS shell on the GaSₓ shell.

16. The method for fabricating the quantum dots according to claim 9, wherein the method, between the step (a) and the step (b), further comprises the step of:
forming a shell on the primary core.

17. The method for fabricating the quantum dots according to claim 16, wherein a composition of the shell on the primary core and a composition of the shell on the secondary core overlap in at least part.

18. The method for fabricating the quantum dots according to claim 9, wherein in the step (b), the Cu fully substitutes the Group 11 element other than Cu.
